(19) United States
(12) Patent Application Publication
(10) Pub. No.: US 2007/0024317 A1
(43) Pub. Date: Feb. 1, 2007

(54) Apparatus for obtaining precision integrated resistors

(76) Inventor: James E. Hansen, Loveland, CO (US)

Correspondence Address: AVAGO TECHNOLOGIES, LTD., P.O. BOX 1920, DENVER, CO, 80201-1920, US

(21) Appl. No.: 11/193,833

(22) Filed: Jul. 29, 2005

(51) Int. Cl. H03K 17/16; H03F 1/36

(52) U.S. Cl. 326/30; 330/86

(57) ABSTRACT

Integrated circuits with on-chip impedance matching techniques, which can be implemented to provide high precision and which greatly increase the precision of resistors integrated into the integrated circuit, are provided.

### BACKGROUND OF THE INVENTION

The present invention relates to on-chip impedance matching circuits, and more particularly, to an apparatus for obtaining precision integrated resistors in CMOS processes.

Mainstream CMOS processes typically do not offer precision resistors, with variation often being twenty percent or more. Circuits needing resistors are generally designed to function with this variation at the expense of performance.

Alternatively, prior art circuits have provided off-chip impedance matching circuits comprising variable resistors or similar devices that can be calibrated to compensate for process/voltage/temperature variations to improve the precision of on-chip resistors.

Unfortunately, the off-chip impedance matching approach is expensive and imposes additional constraints on system architecture. Furthermore, some integrated circuits have hundreds of circuits that require impedance matching circuitry. In these integrated circuits, a separate impedance matching resistor must be coupled to an 1/0 pin connected to each of the circuits requiring impedance matching. Hundreds of impedance matching resistors must be coupled to such an integrated circuit to provide adequate impedance matching. Thus, prior art off-chip impedance matching circuits substantially increase the amount of board space required.

Accordingly, there is a need for a technique for implementing on-chip precision integrated resistors in CMOS processes that allow improved precision of the resistor values without the need for external impedance matching circuitry.

### SUMMARY OF THE INVENTION

According to one aspect of the invention, there is provided an impedance matching apparatus for obtaining precision integrated resistors in integrated circuits. According to another aspect of the invention, there is provided an integrated circuit with on-chip precision resistors for use in impedance matching techniques for functional circuitry. The apparatus of the invention utilizes on- or off-chip precision voltage and precision current sources to adjust a variable resistor implemented on the integrated circuit, for example by selectively switching in parts of a resistor array, until the desired resistance value is obtained. The calibrated resistor is then available for use in functional circuitry requiring matched impedance throughout the chip.

Advantageously, no processing matching is needed for the variable resistor itself because the same resistance being calibrated will actually be used in the functional circuitry, thereby removing processing variation. Depending on how frequently the calibration routine is exercised, the resistance may or may not be at the same temperature during calibration as during normal operation. If it is at the same temperature during calibration, then the variation caused by temperature is also removed. Another advantage is a reduction in the number of off-chip resistors that are coupled to the integrated circuit.

### BRIEF DESCRIPTION OF THE DRAWINGS

A more complete appreciation of this invention, and many of the attendant advantages thereof, will be readily apparent as the same becomes better understood by reference to the following detailed description when considered in conjunction with the accompanying drawings in which like reference symbols indicate the same or similar components, wherein:

FIG. 1 is a schematic diagram of an integrated circuit implementing an impedance matching circuit of the invention;

FIG. 2 is a flowchart illustrating an exemplary method performed by the control logic for adjusting the variable resistor;

FIG. 3 is a flowchart illustrating an alternative exemplary method performed by the control logic for adjusting the variable resistor;

FIG. 4 is a schematic diagram illustrating an example implementation of the impedance matching circuit of FIG. 1; and

FIG. 5 is a schematic diagram of an impedance matching circuit of the invention which utilizes switched capacitor resistors.

### DETAILED DESCRIPTION

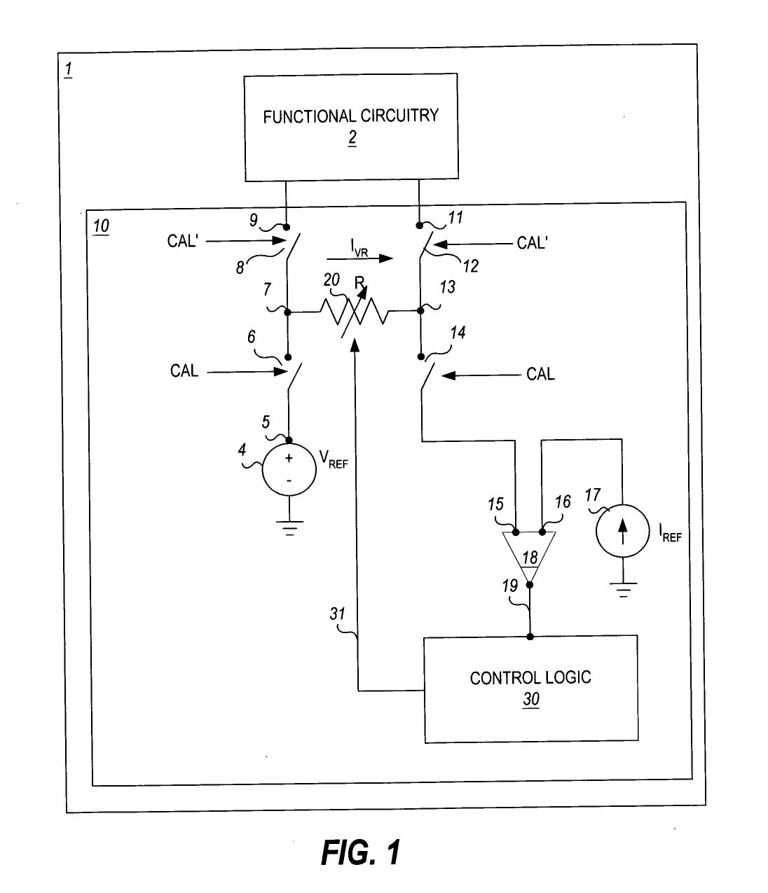

Turning now to the drawings, FIG. 1 is a schematic diagram of an integrated circuit 1 implementing an impedance matching circuit 10 of the invention. As shown, the integrated circuit 1 may comprise one or more functional application circuits 2 that require a precision resistor 20 between functional circuitry nodes 9 and 11.

The integrated circuit 10 comprises a variable resistor 20 whose resistance is controlled by a control signal 31 generated by control logic 30. The variable resistor 20 may be connected between a node 7 that is switchably connected to an output node 5 of a precision voltage source 4 and a node 13 that is switchably connected to a node 15 at an input of a current comparator 18. The precision voltage source 4 may generate a known precise voltage on the node 5.

A precision current source 17 may generate a known precise reference current on a node 16 at another input of the current comparator 18. The current comparator 18 may generate an output signal representing the relative difference between current present at each of its inputs. In a particular embodiment, the output of the current comparator is a binary output representing whether the current I_{VR} across the variable resistor 20 is greater than or less than the reference current I_{REF} generated by the current source 17. The output signal of the current comparator 18 may be output on a node 19.

The node 19 may be connected to an input of control logic 30. Control logic 30 may generate a control signal 31 used by the variable resistor 20 to adjust the resistance of the variable resistor 20.

Node 7 connected to one terminal of the variable resistor 20 is switchably connectable to the output node 5 of the precision voltage source 4 by way of a switch device 6. The state of the switch device 6 is controlled by a calibration enable signal CAL. When the calibration enable signal CAL is in an asserted state, the switch device 6 is closed, connecting node 5 to node 7. When the calibration enable signal CAL is in a deasserted state, the switch device 6 is open, isolating node 5 from node 7.

Node 13 connected to the other terminal of the variable resistor 20 is switchably connectable to an input of the current comparator 18 at node 15 by way of a switch device 14. The state of the switch device 14 is controlled by the calibration enable signal CAL. When the calibration enable signal CAL is in an asserted state, the switch device 14 is closed, connecting node 13 to node 15. When the calibration enable signal CAL is in a deasserted state, the switch device 14 is open, isolating node 13 from node 15.

Functional application circuit 2 may be switchably connectable to node 7, and hence one terminal of the variable resistor 20, by way of switch device 8. The position of the switch device 8 is controlled by an inverted version CAL′ of the calibration enable signal CAL. When the inverted calibration enable signal CAL′ is in an asserted state, the switch device 8 is closed, connecting node 9 to node 7. When the inverted calibration enable signal CAL′ is in a deasserted state, the switch device 8 is open, isolating node 9 from node 7.

Functional application circuit 2 may be switchably connectable to node 13, and hence to the other terminal of the variable resistor 20, by way of switch device 12. The position of the switch device 12 is controlled by an inverted version CAL′ of the calibration enable signal CAL. When the inverted calibration enable signal CAL′ is in an asserted state, the switch device 12 is closed, connecting node 11 to node 13. When the inverted calibration enable signal CAL′ is in a deasserted state, the switch device 12 is open, isolating node 11 from node 13.

In operation, the circuit may be placed in a calibration mode wherein the calibration signal CAL is asserted and the inverted calibration signal CAL′ is deasserted. When the inverted calibration signal CAL′ is deasserted, switches 8 and 12 open, thereby isolating nodes 9 and 11 of the functional circuitry 2 from the terminal nodes 7 and 13 of the variable resistor 20. Since the calibration signal CAL is asserted, switches 6 and 14 close, thereby connecting terminal node 7 to the output 5 of the precision voltage source 4 and terminal node 13 to node 15 at the input of current comparator 18.

In implementation, each of the switch devices 6, 8, 12 and 14 are matched to ensure that the switch devices 6 and 14 vary in the same way with respect to process, voltage, and temperature variations as the switch devices 8 and 12 connected to the functional circuit 2. This ensures that the resistance of the variable resistor 20 will not appear differently to the functional circuit 2 as it did to the calibration circuitry.

The above-identified switch configuration (i.e., switch devices 8 and 12 open and switch devices 6 and 14 closed) results in the precision voltage generated on the output node 5 of the precision voltage source 4 being connected to the terminal node 7 of the variable resistor 20. Since switch device 8 is open, all current flow must go through the variable resistor 20. Further, since switch device 12 is open, all current flow through variable resistor 20 goes through the input of the comparator 18. Simultaneously, the precision current source. 17 generates a known precise reference current I_{REF} on node 16 at the other input of the comparator 18. The current comparator 18 generates one logic level (e.g., a logic high, or “1”) on node 19 if the reference current I_{REF} is greater than the current flow I_{VR} through variable resistor 20 and the other logic level (e.g., a logic low, or “0”) on node 19 if the reference current I_{REF} is less than the current flow I_{VR} through variable resistor 20.

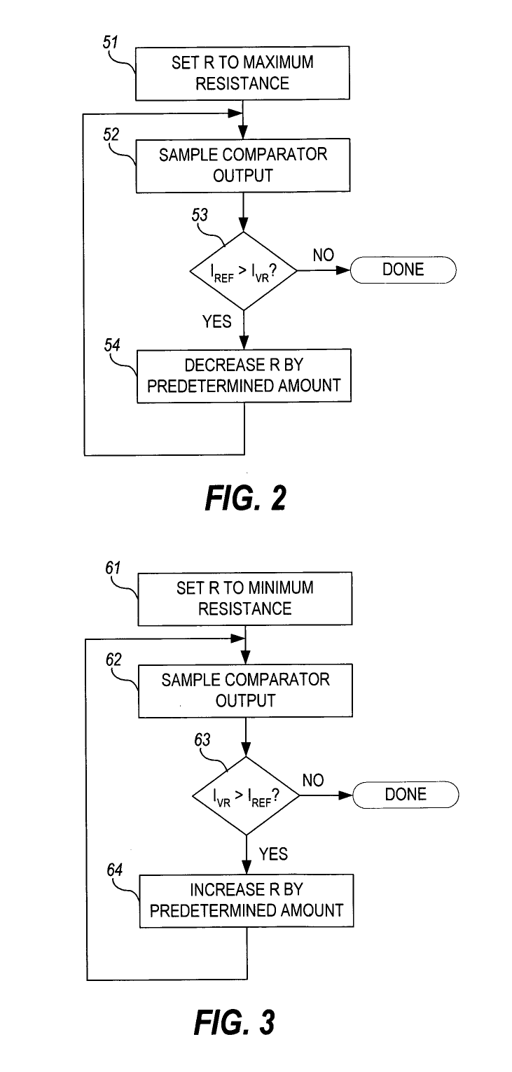

The control logic 30 utilizes the signal on node 19 in determining how to adjust the variable resistor 20 during a calibration mode. FIG. 2 is a flowchart illustrating an exemplary method performed by the control logic for adjusting the variable resistor 20. To this end, the variable resistor 20 R is set to a maximum resistance R_{MAX}, resulting in the smallest current through node 15 seen on the input of the comparator 18 (step 51). The output of the comparator 18 is then sampled (step 52). A determination is made whether the reference current I_{REF} is greater than the current through the variable resistor I_{VR} based on the sampled output of the comparator 18 (step 53). For example, if a high voltage represents a “1”, which is output on node 19 by the comparator 18 only if I_{REF} is in fact greater than I_{VR}, and vice versa, then the control logic 30 need only check to see whether the value present on node 19 is a “1” to determine that I_{REF} is greater than I_{VR}. If I_{REF} is in fact greater than I_{VR}, then the resistance of the variable resistor 20 is reduced by a predetermined amount (step 54), and steps 52 through 54 are repeated until I_{REF}is less than or equal to I_{VR}, at which time the variable resistor 20 is considered calibrated.

FIG. 3 is a flowchart illustrating an alternative exemplary method performed by the control logic for adjusting the variable resistor 20. To this end, the variable resistor 20 R is set to a minimum resistance R_{MIN}, resulting in the highest current on node 15 seen on the input of the comparator 18 (step 61). The output of the comparator 18 is then sampled (step 62). A determination is made whether the reference current I_{VR} is greater than the current through the variable resistor I_{REF} based on the sampled output of the comparator 18 (step 63). For example, if a low voltage represents a “0”, which is output on node 19 by the comparator 18 only if I_{VR} is in fact greater than I_{REF}, and vice versa, then the control logic 30 need only check to see whether the value present on node 19 is a “0” to determine that I_{VR} is greater than I_{REF}. If I_{VR} is in fact greater than I_{REF}, then the resistance of the variable resistor 20 is increased by a predetermined amount (step 64), and steps 62 through 64 are repeated until I_{VR} is less than or equal to I_{REF}, at which time the variable resistor 20 is considered calibrated.

The choice in resistive step may be implemented according to one of many different step algorithms, for example according to a thermometer code, a binary-weighted code, a hybrid code, etc. A detailed description of each of these codes is described in detail in U.S. patent application Ser. No. 10/835,906 to Humphrey, filed on Apr. 30, 2004, and entitled “Hybrid Binary/Thermometer Code For Controlled-Voltage Integrated Circuit Output Drivers”, which is hereby incorporated by reference herein for all that it teaches. Other implementations may be used for selecting the resistance at each step.

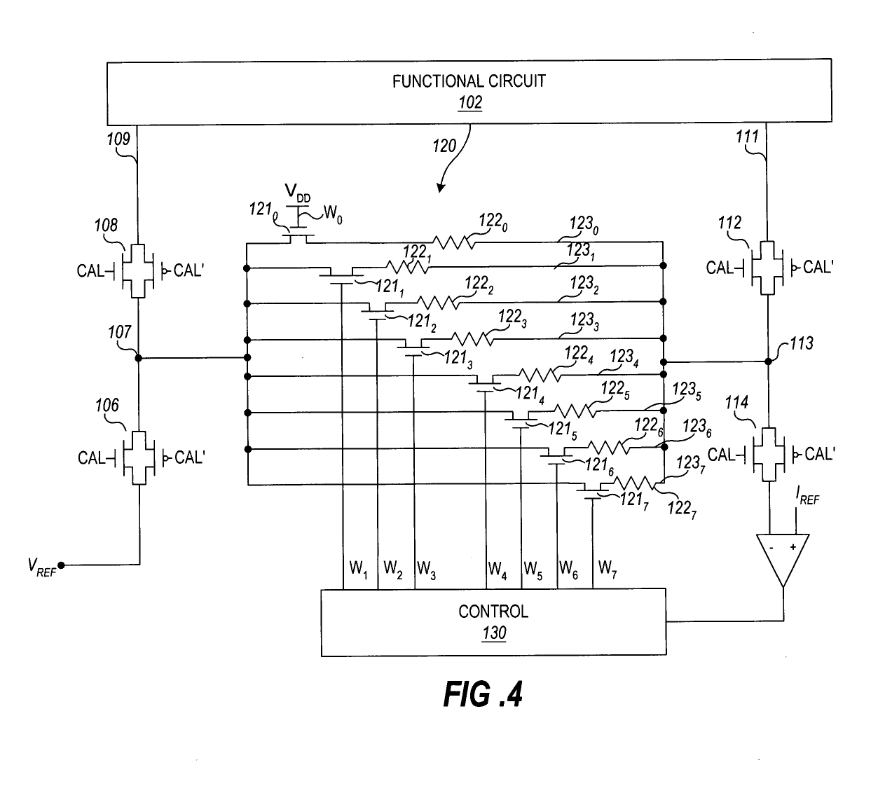

FIG. 4 is a schematic diagram illustrating an example implementation 100 of the impedance matching circuit 10 of FIG. 1. As illustrated, the variable resistor 20 is implemented with a programmable switched resistor array 120 comprising a plurality of resistors 122₀, . . . , 122₇ switchably connected in parallel between nodes 107 and 113. Each resistor 122₀, 122₇ is switchably connectable between nodes 107 and 113 by respective FET devices 121₀, . . . , 121₇. Respective FET devices 121₀, . . . , 121₇ are connected in series with their respective resistors 122₀, . . . , 122₇, operating to either connect or isolate their respective resistance between nodes 107 and 113. The switch states of the respective FET devices 121₀, . . . , 121₇ are programmable by control logic 130 that implements a resistive step method such as the method shown in FIG. 2 or in FIG. 3. The reference voltage V_{REF} is generated on- or off-chip depending on the balance between the need for precision and the need for space. Many well-known methods beyond the scope of this invention are known for generating a precision voltage source, and the invention is intended to cover any such voltage source. Likewise, many well-known methods beyond the scope of this invention are known for generating a precision current source, and the invention is intended to cover any such current source. Again, the current source may be implemented on- or off-chip.

As also shown, the switch devices 6, 8, 12 and 14 are each implemented with matching FET devices, preferably using transmission gates (or “T-gates”) 106, 108, 112, and 114, as shown.

The resistance network 120 includes a resistive leg 1230 that is connected between node 107 and node 113, and a plurality of impedance legs 123₁, . . . , 123₇ programmably electrically connectable in parallel between node 107 and node 113 by the control circuit 130. In the preferred embodiment, each of the FET devices 121₀, . . . , 121₇ is defined by a channel width that defines the admittance of that FET device. When activated (i.e., turned on to conduct current), each FET device provides an electrical connection between node 107 and a first terminal of its corresponding resistor 122₀, . . . , 122₇. The other terminal of the corresponding resistor 122₀, . . . , 122₇ is connected to node 113. Activation of a FET device thereby allows current flow between nodes 107 and 113 such that the respective corresponding resistor 122₀, . . . , 122₇ contributes to the combined parallel resistance of the impedance network. When more than one of the FET devices 121₀, . . . , 121₇ is turned on, the characteristic resistance of the enabled FETs combine in parallel to provide a lower combined resistance. In this way, the output resistance of the resistance network 120 may be varied.

In the embodiment shown, the impedance leg 123₀ is always activated, allowing a signal to pass from node 107 to node 113 in order to prevent impedance jumps which can result in noise glitches on the input nodes 109 and 111 of the functional circuitry 102 that may occur momentarily as a result of the switching on or off of the impedance legs 123₁, . . . , 123₇.

The control circuit 130 generates a digital calibration word W_{1::7} to activate selected ones of the switchable resistance legs 123₁, . . . , 123₇ to precisely control the resistance of the variable resistor 120 in accordance with one of the methods described in FIGS. 2 or 3, or using other step decision functionality. Each respective bit in the calibration word W_{1::7}corresponds to, and controls, a different one of the resistance legs 123₁, . . . , 123₇. In the preferred embodiment, each respective bit W₁, through W₇ of the calibration word W_{1::7} drives a different respective gate of a corresponding respective resistance legs 121₁, . . . , 121₇ implementing the respective corresponding resistance legs 123₁, . . . , 123₇.

In the illustrative embodiment, the admittances of resistance legs 123₁, . . . , 123₇ of the impedance network 120 may be weighted to implement the chosen code of the controller. For example, in a binary weighted code, each resistance leg in the resistance network has an admittance of 2(^{bit position})Y, where Y is a predefined minimum admittance appropriate to the design. In other words, if bit B₀ of a binary-coded calibration word B_{0::n-1}controls a FET with admittance Y, bit B₁. of the calibration word B_{0::n-1} controls a FET with admittance 2*Y, bit B₂ of the calibration word B_{0::n-1} controls a FET with admittance 4*Y, and so on. Thus, the impedance of each leg of the resistance network corresponds to the weighted position of the bit in the binary code that controls the leg.

In a thermometer code, the admittances of the resistance legs 123₁, . . . , 123₇ may be weighted equally. Other codes may require different weighting of the admittances of the resistance legs.

The above described impedance matching circuit allows increased calibration precision of integrated resistors in integrated circuits. The above design allows high-precision on the order of 1% or less tolerance in resistance values. Compared to 10 or even 20% tolerance in prior art integrated resistors, the invention adds a clear contribution to integrated circuit designs.

In any given integrated circuit, the determination of when to calibrate the resistor depends on the design. Calibration can be performed once at power-up, periodically after power-up, or upon demand via external programming.

Those skilled in the art will appreciate that other equivalent implementations are possible. For example, there are many different circuits that can be used as a current source and many different circuits that can be used as a voltage source. The variable resistor 20 may be implemented as a resistor array, a field effect transistor (FET) array, or any other variable resistance equivalent, and may be implemented as a series array, a parallel array, or combination.

The current and/or voltage source may alternatively be implemented using a precision capacitor circuit with a precision clock. Capacitors are relatively simple to implement and generate a precise voltage when the clock signal is accurate. Integrating the charge over time results in voltage. The circuit then breaks down into comparing two voltages.

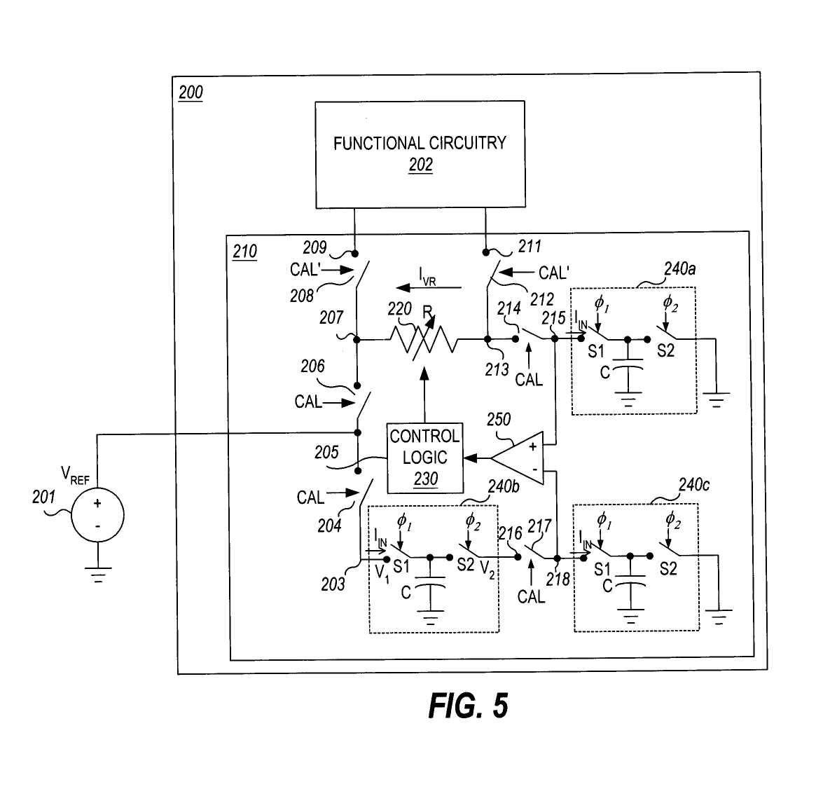

FIG. 5 is a schematic diagram of an impedance matching circuit 210 of the invention for an integrated circuit 200 which utilizes switched capacitor resistors 240a, 240b, 240c in place of current sources. In this implementation, φ1 and φ2 are non-overlapping complementary clock signals that close the corresponding switches to capacitor C for each period T of the clock.

As known by those skilled in the art, q=CV and I=Δq/T, where q is charge, C is capacitance, V is voltage, I is current, and T is time. In the circuit of FIG. 5, one will recognize that the same current that flows into a switched capacitor resistor network 240a, 240b, 240c through the respective first switch S1 must flow also flow out of the respective second switch S2. Therefore, 1ᵢₙ=Δq₁=Δq₂=C/T(V₁- V₂). Since I=V/R, then from the preceding equation R=T/C. Since T and C can both be controlled, so can R. Thus, The circuit again breaks down into comparing two voltages on the input of voltage comparator 250, whose output is fed to the controller 230 for controlling the resistance value of the variable resistor 220.

Although this preferred embodiment of the present invention has been disclosed for illustrative purposes, those skilled in the art will appreciate that various modifications, additions and substitutions are possible, without departing from the scope and spirit of the invention as disclosed in the accompanying claims. It is also possible that other benefits or uses of the currently disclosed invention will become apparent over time.

What is claimed is:

1. An apparatus for obtaining a precision integrated resistor on an integrated circuit, comprising:
a comparator having an output terminal, a first input terminal, and a second input terminal, the second input terminal connected to receive a precision reference current;
a variable resistor operable to vary in resistance in response to a control signal, the variable resistor having a first terminal switchably connected to receive a precision reference voltage and a second terminal switchably connected to the first input terminal of the comparator; and
control logic operable to receive an output signal from the output terminal of the comparator and to generate the control signal in response to the output signal.

2. The apparatus of claim 1, wherein:
the precision reference current is generated external to the integrated circuit.

3. The apparatus of claim 1, wherein:
the precision reference voltage is generated external to the integrated circuit.

4. The apparatus of claim 1, wherein:
the precision reference current is generated on the integrated circuit.

5. The apparatus of claim 1, wherein:
the precision reference voltage is generated on the integrated circuit.

6. The apparatus of claim 1, wherein the precision of the variable resistor can be controlled to within approximately 1% of the resistor value.

7. The apparatus of claim 1, wherein the precision reference current is generated by a switched capacitor resistor network comprising at least one precision clock and at least one precision capacitor to obtain a precision resistor for use in calibrating a continuous time resistor.

8. The apparatus of claim 7, wherein:
the precision reference current is generated by a first switched capacitor, the first switched capacitor comprising a first capacitor having a first capacitor terminal and a second capacitor terminal, the second capacitor terminal connected to a circuit ground, the first switched capacitor further comprising a first switch device connected between the second input terminal of the comparator and the first capacitor terminal and controlled by a first clock signal, the first switched capacitor further comprising a second switch device connected between the first capacitor terminal and the circuit ground and controlled by a second clock signal, the second clock signal being a complementary and non-overlapping version of the first clock signal.

9. The apparatus of claim 8, wherein:
the first input terminal of the comparator is connected between a second switched capacitor and a third switched capacitor;
the second switched capacitor comprising a second capacitor having a first capacitor terminal and a second capacitor terminal, the second capacitor terminal connected to a circuit ground, the second switched capacitor further comprising a first switch device connected between a voltage source and the first capacitor terminal and controlled by the first clock signal, the second switched capacitor further comprising a second switch device connected between the first capacitor terminal and the first input terminal of the comparator and controlled by the second clock signal; and
the third switched capacitor comprising a third capacitor having a first capacitor terminal and a second capacitor terminal, the second capacitor terminal connected to a circuit ground, the third switched capacitor further comprising a first switch device connected between the first input terminal of the comparator and the first capacitor terminal and controlled by the first clock signal, the second switched capacitor further comprising a second switch device connected between the first capacitor terminal and the circuit ground and controlled by the second clock signal.

10. An integrated circuit, comprising:
a voltage comparator having an output terminal, a first input terminal, and a second input terminal, the second input terminal connected to receive a first precision reference voltage;
a variable resistor operable to vary in resistance in response to a control signal, the variable resistor having a first terminal switchably connected to receive a second precision reference voltage and a second terminal switchably connected to the first input terminal of the comparator;
control logic operable to receive an output signal from the output terminal of the comparator and to generate the control signal in response to the output signal; and
a functional circuit comprising a first node coupled to the first terminal of the variable resistor and a second node coupled to the second terminal of the variable resistor.

11. The integrated circuit of claim 10, wherein:
the control logic is operable to calibrate the variable resistor to match an impedance of the functional circuit.

12. The integrated circuit of claim 10, further comprising:
a first switch device which operates to connect the first node of the functional circuit to the first terminal of the variable resistor in response to a first signal and to disconnect the first node of the functional circuit from the first terminal of the variable resistor in response to a second signal; and
a second switch device which operates to connect the second node of the functional circuit to the second terminal of the variable resistor in response to the first signal and to disconnect the second node of the functional circuit from the second terminal of the variable resistor in response to the second signal;
a third switch device which operates to connect the first terminal of the variable resistor to the second precision reference voltage in response to the second signal and to disconnect the first terminal of the variable resistor from the second precision reference voltage in response to the first signal; and
a fourth switch device which operates to connect the second terminal of the variable resistor to the first input terminal of the comparator in response to the second signal and to disconnect the second terminal of the variable resistor from the first input terminal of the comparator in response to the first signal.

13. The integrated circuit of claim 12, wherein the first signal is active during a normal operating mode and the second signal is active during a calibration mode, and the first signal and the second signal are not active simultaneously.

14. The integrated circuit of claim 10, wherein the precision of the variable resistor can be controlled to within approximately 1% of the resistor value.

15. The integrated circuit of claim 7, wherein:
the first precision reference voltage is generated by a first switched capacitor, the first switched capacitor comprising a first capacitor having a first capacitor terminal and a second capacitor terminal, the second capacitor terminal connected to a circuit ground, the first switched capacitor further comprising a first switch device connected between the second input terminal of the comparator and the first capacitor terminal and controlled by a first clock signal, the first switched capacitor further comprising a second switch device connected between the first capacitor terminal and the circuit ground and controlled by a second clock signal, the second clock signal being a complementary and non-overlapping version of the first clock signal.

16. The integrated circuit of claim 15, wherein:
the first input terminal of the comparator is connected between a second switched capacitor and a third switched capacitor; the second switched capacitor comprising a second capacitor having a first capacitor terminal and a second capacitor terminal, the second capacitor terminal connected to a circuit ground, the second switched capacitor further comprising a first switch device connected between a voltage source and the first capacitor terminal and controlled by the first clock signal, the second switched capacitor further comprising a second switch device connected between the first capacitor terminal and the first input terminal of the comparator and controlled by the second clock signal; and
the third switched capacitor comprising a third capacitor having a first capacitor terminal and a second capacitor terminal, the second capacitor terminal connected to a circuit ground, the third switched capacitor further comprising a first switch device connected between the first input terminal of the comparator and the first capacitor terminal and controlled by the first clock signal, the second switched capacitor further comprising a second switch device connected between the first capacitor terminal and the circuit ground and controlled by the second clock signal.

17. A method for obtaining a precision integrated resistor, the method comprising the steps of:
isolating a first terminal and a second terminal of a variable resistor from functional circuitry;
generating a precision reference voltage on the first terminal of a variable resistor;
comparing a precision reference current with current generated on the second terminal of the variable resistor due to the precision reference voltage; and
adjusting a resistance value of the variable resistor in response to results of the comparing step.

18. The method of claim 17, further comprising the steps of:
repeating the comparing and adjusting steps until the precision reference current is within a predetermined range of the current generated on the second terminal of the variable resistor due to the precision reference voltage;
isolating the first terminal of the variable resistor from the precision reference voltage and isolating the second terminal of the variable resistor from the first input terminal of the comparator;
connecting the first terminal and the second terminal of the variable resistor to respective first and second nodes of the functional circuitry.
